(19) United States
(12) Patent Application Publication
(10) Pub. No.: US 2006/0228864 A1
(43) Pub. Date: Oct. 12, 2006

(54) Semiconductor devices having a bottle-shaped deep trench capacitor and methods for making the same using Epi-Si growth process

(75) Inventors: Hsi-Chieh Chen, Jhubei City (TW); Chuan-Chi Chen, Jhubei City (TW)

Correspondence Address: AKIN GUMP STRAUSS HAUER & FELD L.L.P., ONE COMMERCE SQUARE, 2005 MARKET STREET, SUITE 2200, PHILADELPHIA, PA, 19103, US

(73) Assignee: PROMOS Technologies Inc.

(21) Appl. No.: 11/103,948

(22) Filed: Apr. 12, 2005

(51) Int. Cl. H01L 21/76

(52) U.S. Cl. 438/400

(57) ABSTRACT

A semiconductor device having a transistor and a storage capacitor. The transistor includes source and drain regions formed on a substrate. The storage capacitor is coupled to the transistor. The storage capacitor is formed from a bottle-shaped trench and having an Epi-Si layer grown inside the trench to form at least part of one of the source and drain regions. The Epi-Si layer can be selectively grown inside the trench from portions of the substrate such that the Epi-Si layer is used to define a bottle-shape for the trench.

### FIELD

This invention relates generally to semiconductor devices and fabrication methods and, more particularly, to semiconductor devices having a bottle-shaped deep trench capacitor and methods for making the same using Epi-Si growth process.

### BACKGROUND

Semiconductor devices, such as memory devices, typically include transistors connected to storage capacitors. For example, as shown in FIG. 1, a basic memory cell 100 for a dynamic random access memory (DRAM) device includes a transistor 102 having a gate (G) connected to a word line 106, a drain (D) connected to a bit line 104, and a source (S) connected to a storage capacitor 108. The storage capacitor 108 stores the data applied on the bit line 104, which is passed through the transistor 106 when it is turned on. The transistor 102 is turned on by a signal applied on the word line 106. In early memory devices, the storage capacitor was formed in a planar manner on the surface of the substrate adjacent to the transistor. A limitation with this layout is that it inefficiently uses area on the substrate. In certain cases, in order to increase memory density, the circuit dimensions of the transistor and storage capacitor are reduced. However, reducing the dimensions of the storage capacitor can prevent the capacitor from storing a sufficient amount of electric charge and deteriorate the operation of a memory device.

To address these limitations, deep trench storage capacitors were proposed. For these types of capacitors, a deep trench is etched into a substrate in order to occupy less surface area of the substrate. A thin dielectric insulator and a doped polysilicon layer are formed in the trench, and buried-plate diffusion regions are formed in the substrate. The polysilicon layer and diffusion regions serve as electrodes of the capacitor. An isolation collar is also formed in the trench to prevent charge leakage. As the size of memory devices decrease, the area on a substrate for making a memory cell, including a transistor and a storage capacitor, becomes even more compact. As a result, the amount of surface area allowed is further restricted when making the trench. This can affect the ability of the storage capacitor to provide sufficient electric charge.

For deep trench storage capacitors, if higher capacitance is needed, a deeper trench is required. In order to form a deeper trench, however, the opening of the trench needs to be large to allow for proper etching within the trench. This encroaches the surface area provided by a substrate. Enlarging the opening of a trench, however, causes the storage capacitors and transistors to be formed closer together. When the storage capacitors and transistors are formed closer together, the circuit layouts are prone to shorts and other adverse electrical characteristics. In addition, forming a deeper trench can cause subsequent processing steps to be more complex when forming polysilicon layers and buried diffusion regions in the deep trench.

To avoid enlarging the opening of a trench, one technique proposed is to form a bottle-shaped trench storage capacitor. A bottle-shaped trench storage capacitor allows for increased capacitance by enlarging laterally the surface area inside the trench—i.e., the trench can have a neck section that is narrower that its body section forming a shape of a bottle. FIGS. 3A-3H illustrate prior art steps of forming a bottle-shaped trench for a storage capacitor. Referring to FIG. 3A, an oxide mask 302 is formed over substrate 300 and patterned to expose an open area on substrate 300. The exposed area of substrate 300 is etched away to form a deep trench 301. Referring to FIG. 3B, a thermal oxide layer 306 is formed in trench 301 and a nitride liner 304 is formed on the thermal oxide layer 306. Referring to FIG. 3C, an amorphous silicon (A-Si) layer 308 is formed in the trench 301 on the nitride liner 304 and then a subsequent nitride liner 309 is formed on the A-Si layer 308. Referring to FIG. 3D, the trench 301 is filled with a resist fill 310 on the nitride liner 309.

Referring to FIG. 3E, the resist fill 310 is polished to form a smooth surface above the oxide mask 302. Referring to FIG. 3F, the photoresist fill 310 and nitride liner 309 are recessed and etched back to a predetermined depth level in the trench 301. By etching back the nitride liner 309, the A-Si layer 308 above the certain depth level of the resist fill 310 is exposed. Referring to FIG. 3G, the resist fill 310 is stripped and removed from within the trench 301 and the exposed A-Si layer 308 is oxidized to form SiO₂ layer 312, which acts as a masking layer. Referring to FIG. 3H, a bottle etching process is used to remove the nitride liner 309, A-Si layer 308, nitride liner 304, and thermal oxide layer 306 in the trench 301 below the SiO₂ layer 312. A subsequent wet etching process is used to enlarge the bottom section of the trench 310 to further define a bottle-shaped trench for a storage capacitor.

A disadvantage of this prior technique for forming a bottle-shaped trench is that the fabrication processes within the trench is difficult to control for a storage capacitor. For instance, the prior technique requires complicated masking layers in the top section of the trench for subsequent processing in the lower section of the trench. The masking layers in the top section, e.g., the SiO₂ masking layer, makes the opening in the trench narrower. Consequently, the narrower opening makes subsequent etching processes difficult to control when removing the nitride liners and silicon and oxide layers from within the trench. Furthermore, enlarging the bottom body section of the trench to form the bottle-shape in the trench is difficult to control if it is limited by a narrow opening to the trench.

Thus, what is needed is an improved bottle-shaped trench capacitor for semiconductor devices, such as DRAM memory devices, and fabrication methods for making the same.

### SUMMARY

According to one aspect of the invention, a semiconductor fabrication method is disclosed. A trench is formed in a substrate. An Epi-Si layer is formed from portions of the substrate such that the Epi-Si layer is used to define a bottle-shape for the trench. According to another aspect of the invention, a semiconductor device is disclosed having a trench formed in a substrate and an Epi-Si layer formed from portions of the substrate in the trench. The Epi-Si layer is used to define a bottle-shape for the deep trench.

According to another aspect of the invention, a semiconductor device is disclosed having a transistor and a storage capacitor. The transistor includes source and drain regions formed on a substrate. The storage capacitor is coupled to the transistor through an electrical connection and is formed from a bottle-shaped trench and having an Epi-Si layer grown inside the trench to form at least part of one of the source and drain regions. According to another aspect of the invention, a semiconductor fabrication method is disclosed. A transistor is formed on a substrate having source and drain regions. A storage capacitor is formed that is coupled the transistor. The storage capacitor is formed from a bottle-shaped trench and having and an Epi-Si layer grown inside the trench to form at least part of one of the source and drain regions.

### BRIEF DESCRIPTION OF THE DRAWINGS

The accompanying drawings, which are incorporated in and constitute part of this specification, illustrate examples, implementations, and embodiments of the invention, and together with the description, serve to explain the principles of the invention. In the drawings,

FIG. 1 illustrates one example of a DRAM memory cell connected to a wordline and a bitline;

FIG. 2 illustrates a simplified cross-sectional diagram of a DRAM memory cell 200 having a bottle-shaped deep trench storage capacitor with Epi-Si growth regions or layers according to one example;

FIGS. 3A-3H are cross-sectional diagrams of a semiconductor device to illustrate prior art steps of forming a bottle-shaped trench for a storage capacitor;

FIGS. 4A-4G are cross-sectional diagrams of a semiconductor device to illustrate the steps of forming a bottle-shaped trench using an Epi-Si growth process for a storage capacitor according to one example;

FIGS. 5A-5C are cross-sectional diagrams of a semiconductor device to illustrate the steps of forming a bottle-shaped trench using a partial selective Epi-Si growth process for a storage capacitor according to one example; and

FIG. 6 is one example circuit layout that uses a bottle-shaped deep trench capacitor with epi-si growth.

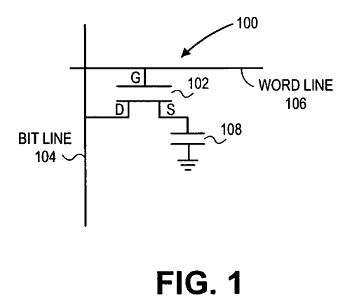

### DETAILED DESCRIPTION

Reference will now be made in detail to the exemplary embodiments of the invention, examples of which are illustrated in the accompanying drawings. Wherever possible, the same reference numbers will be used throughout the drawings to refer to the same. The following example semiconductor devices and methods overcome disadvantages of prior devices and methods for forming a deep trench storage capacitor.

According to one example, a semiconductor fabrication method is described. A trench is formed in a substrate. An Epi-Si layer is formed from portions of the substrate such that the Epi-Si layer is used to define a bottle-shape for the trench. By using an Epi-Si layer formed from the substrate to define the bottle-shape for the trench, complicated processes for forming masking or protection layers in the top section of the trench are not necessary. Furthermore, a larger opening can be used for processing in the bottom section of the trench for making, e.g., a buried plate and necessary capacitor node and dielectric layers.

Additionally, according to another example, a semiconductor device is described having a transistor and a storage capacitor. The transistor includes source and drain regions formed on a substrate. The storage capacitor is coupled to the transistor through an electrical connection and is formed from a bottle-shaped trench and having an Epi-Si layer grown inside the trench to form at least part of one of the source and drain regions. The Epi-Si layer can be selectively grown inside the trench. By using an Epi-Si layer that forms part of the source or drain regions a larger deep trench can be formed, while efficiently using surface area space on a substrate. The following techniques also provide an improved fabrication process for making a storage capacitor that can minimize process control concerns.

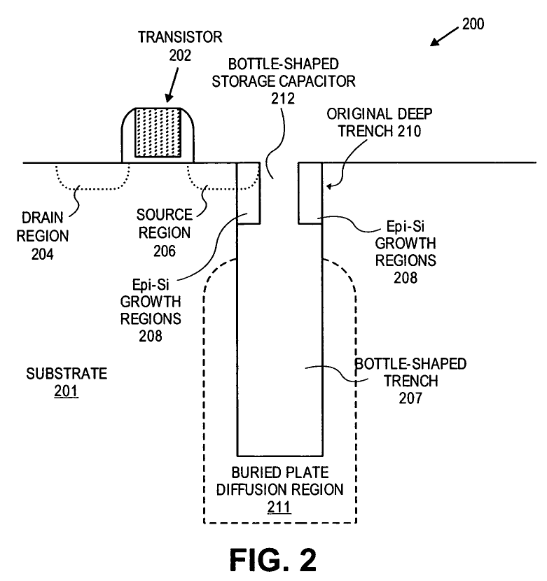

FIG. 2 is a simplified exemplary cross-sectional diagram of a semiconductor device having a bottle-shaped deep trench with Epi-Si growth regions or layers. In this example, the semiconductor device can refer to a DRAM memory device having a memory cell 200. The memory cell 200 includes a transistor 202 with a drain region 204 and a source region 206. An active region lies below the transistor and in between the drain and source regions 204 and 205. Adjacent to the transistor 202 and source region 206 is a bottle-shaped storage capacitor 212 having a bottle-shaped trench 207. Originally, a deep trench 210 was formed in substrate 201, and after subsequent processing, which will be described in further detail below, the bottle-shaped trench 207 is defined by growing an epitaxial Si layer from portions of the substrate 201 at the top of the trench 207. A buried plate diffusion region 211 is also formed in substrate 201 to form one of the capacitor electrodes for storage capacitor 212. Other layers of the storage capacitor 212, such as the node, dielectric, collar, and connecting layers can also be formed the bottle-shaped trench 207, however, these layers are not shown in FIG. 2 so as not to obscure the diagram.

In the example in FIG. 2, the forming of the Epi-Si growth regions or layers 208 is used to define the bottle-shaped trench 207. In particular, the neck section is defined in between the Epi-Si growth regions 208 and the body section is defined below the Epi-Si growth regions from the original etching to form original deep trench 210, which can occur prior to the growth of the Epi-Si growth regions 208. In this manner, a larger opening to the trench 210 can be used for processing in the lower section trench 207 to form the bottle-shaped storage capacitor 212. Furthermore, complicated masking layers inside the trench and processing is not needed to protect the top section of the trench 207 overcoming disadvantages of prior techniques that require masking layers in the top section of the trench when processing is required to enlarge the bottom section of the trench.

In addition, in the example of FIG. 2, the Epi-Si growth regions 208 can be used to form part of any of the doped regions for transistor 202. In certain examples, the Epi-Si regions 206 are formed and doped along with portions of substrate 201 adjacent to transistor 202 to form an electrical connection, such as source region 206. By using the Epi-Si growth regions 208 to form part of a doped region for a transistor 202 (e.g., source region 206), the memory cell 202 can gain back surface area on substrate 201 and allowing the transistor 202 and bottle-shaped storage capacitor 212 to more efficiently use surface area on substrate 201.

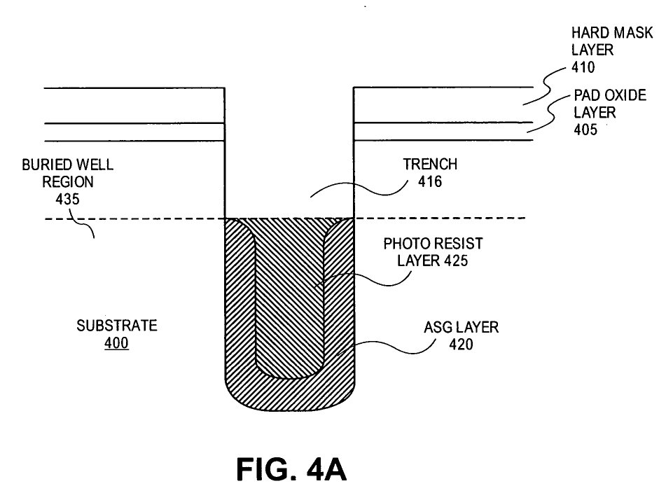

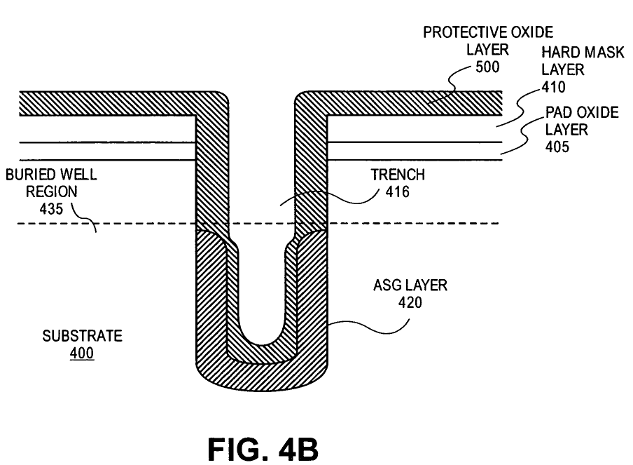

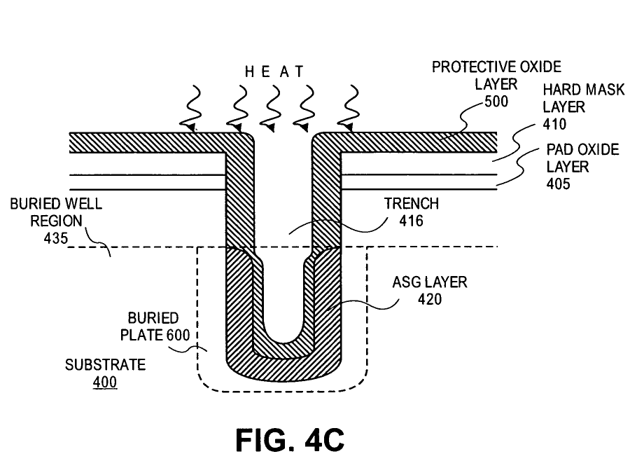

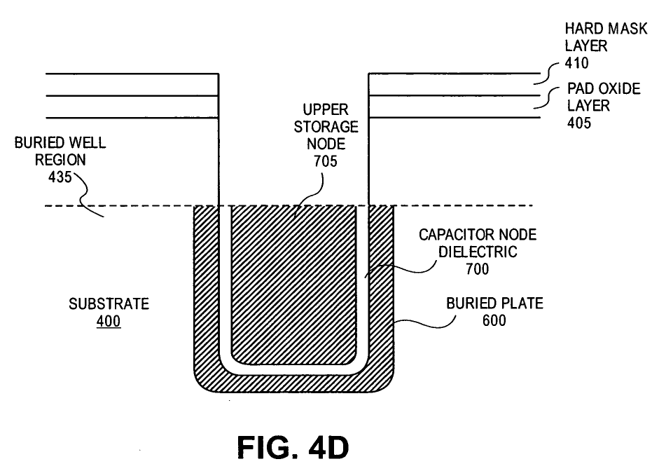

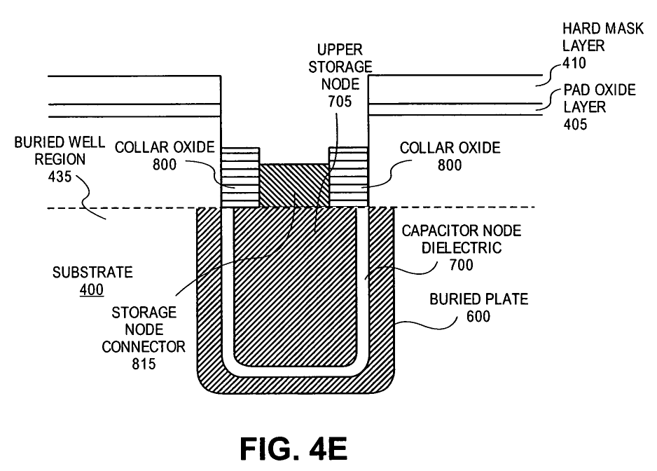

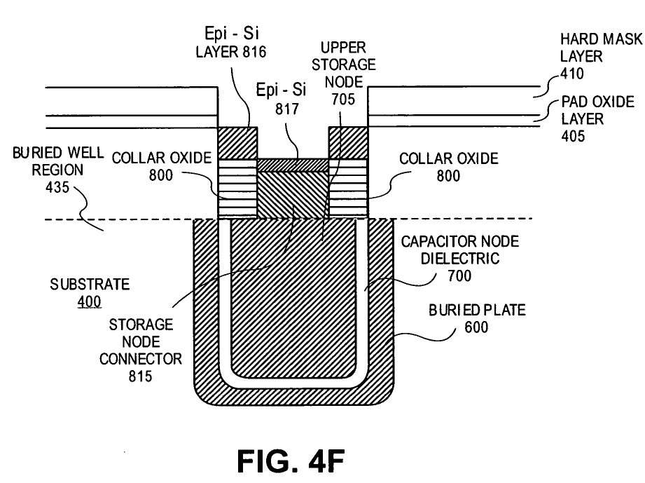

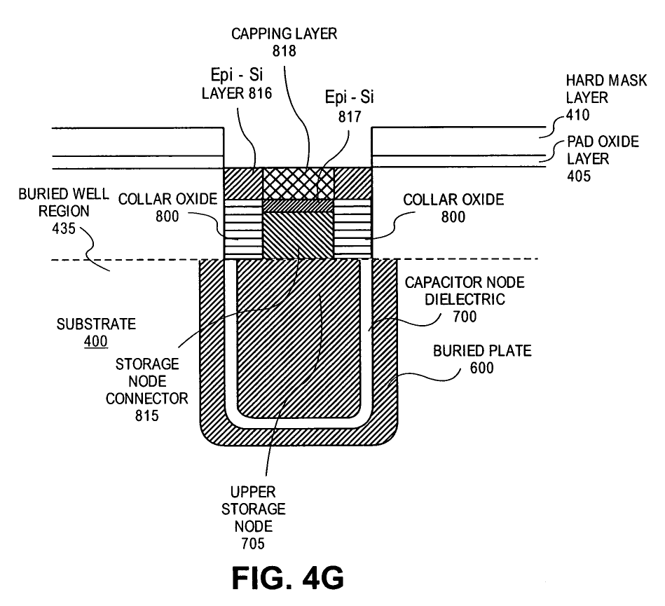

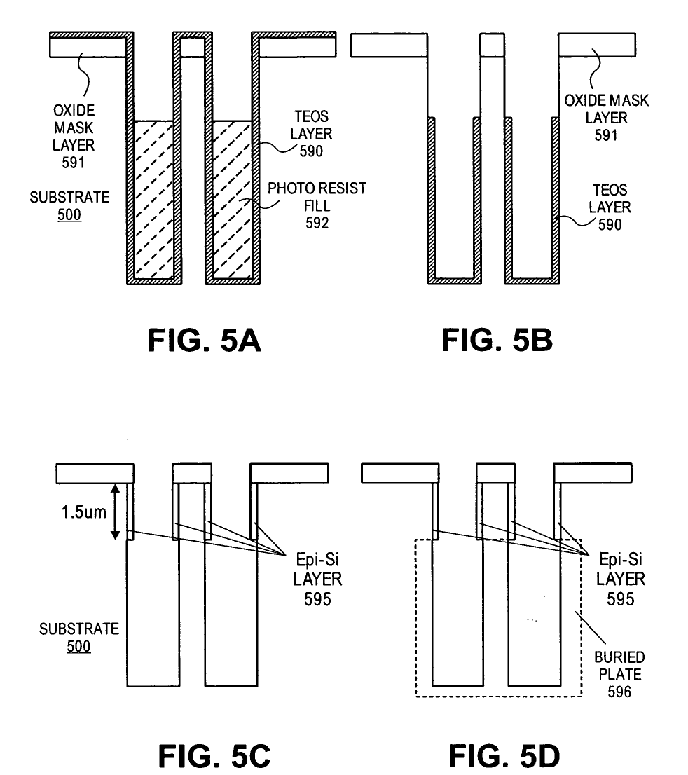

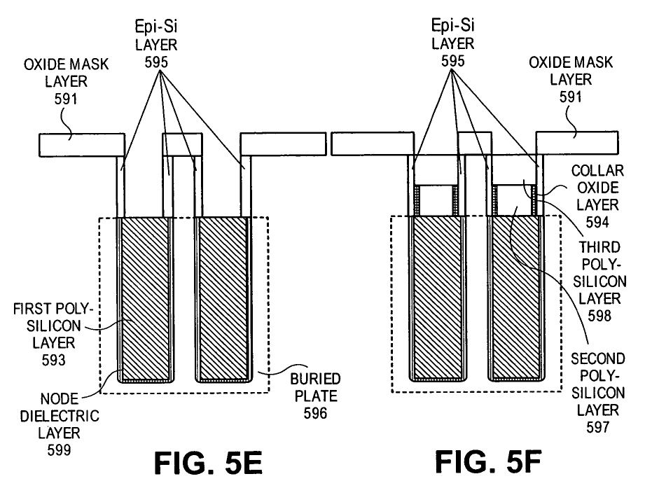

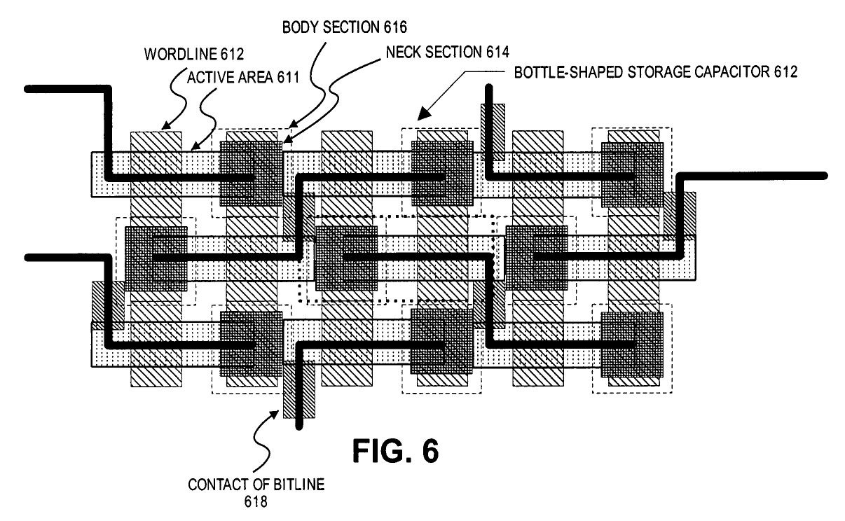

For example, FIG. 6 illustrates a top view of a circuit layout according to one example that utilizes bottle-shaped storage capacitors 612 with the neck section 614 and body section 616, wherein blocks 611, 612, and 618 represent the active areas, word lines, and contacts of bit lines, respectively. Storage capacitors 612 can implement bottle-shaped storage capacitors described herein. By using such bottle-shaped storage capacitors, the layout of a memory device can be maximized wherein the bottle-shaped storage capacitors 612 are spaced apart efficiently so as not cause electrical interference or shorts. The process of forming the bottle-shaped trenches and storage capacitors will now be described with respect to FIGS. 4A-4G and 5A-5F.

FIGS. 4A-4G are cross-sectional diagrams of a semiconductor device to illustrate the steps of forming a bottle-shaped trench using an Epi-Si growth process for a storage capacitor according to one example. Referring to FIG. 4A, a pad oxide 405 and a hard mask layer 410 are formed and patterned on a semiconductor substrate 400. A hard mask layer 410 is then formed and patterned the pad oxide layer 405. The hard mask layer 410 may include silicon nitride and be formed on the pad oxide 405 using a chemical vapor deposition (CVD) process. The pad oxide layer 405 can reduce the interfacial stress between the hard mask layer 410 and the substrate 400. The pad oxide 405 and hard mask layer 410 can be used to expose an area of substrate 400 and provide a protection layer for substrate 400. In this example, a buried well region 435 is defined in the substrate below the dash lines half way in the trench 416. The exposed area of the substrate 400 is then etched (e.g., using a dry etch process) to form a deep trench 416.

After the trench 416 is formed, an arsenosilicate glass (ASG) layer 420 is formed over substrate 400 and in trench 416 and then a photoresist layer 425 is formed in the trench 416 on the ASG layer 420. The photoresist layer 425 is then recessed or etched back to a predetermined height (e.g., to the height shown by the dash lines outlining the boundary of the buried well region 435). The upper portion of the ASG layer 420 is then removed to the predetermined height in the trench 416. The resulting device is shown in FIG. 4A.

Referring to FIGS. 4B and 4C, the remaining photoresist layer 425 is removed and then a protective oxide layer 500 is formed over the substrate 400 and in the trench 416 and on the remaining ASG layer 420 in the trench 416. The protective oxide layer 500 can include tetraehtylorthosilicate (TEOS) that can be deposited with a thickness, e.g., of about 40 nm to about 60 nm. Then an annealing or high-temperature annealing process (thermal drive-in process) is performed on the device such that dopants in the ASG layer (e.g., dopants such as n⁺ dopants including arsenic or phosphorus) are diffused into the buried well region 435 to form a buried plate 600 for a storage capacitor. The protective oxide layer 500 prevents the dopants from diffusing outside of the buried well region 435. The protective oxide layer 500 confines the dopants to diffuse into the lower half of the trench 416 by preventing dopants from laterally diffusing through the upper sidewall of the trench 416. In certain examples, the thermal drive-in process is performed at a temperature of about 1050° C. for about 30 minutes. Alternatively, the thermal drive-in process can be performed at a temperature of about 1000° C. for about 45 minutes.

Referring to FIG. 4D, the protective oxide layer 500 and the ASG layer 420 are then removed by using wet etch or dry etch process. For example, a chemical wet etch process can be used to remove the protective oxide layer 500 and the ASG layer 420. A capacitor node dielectric layer 700 is then formed on the sidewalls and bottom of the trench 416. Subsequently, an upper storage node 705 is formed in the trench 416 by depositing a first polysilicon layer in the trench 416 and etched back to provide coverage of the buried plate region 435 of the capacitor. In certain examples, the first polysilicon layer or upper storage node 705 is recessed or polished back to the buried plate region 435.

The capacitor node dielectric layer 700 can also be etched using a wet etch process to remove portions of the capacitor node dielectric layer 700 and reduce the height of the dielectric material at the level of the buried-plate region. The capacitor node dielectric layer 700 may include silicon nitride. This layer can then be exposed to an oxidizing atmosphere to form the capacitor node dielectric of the cell capacitor(e.g., SiN, NO, ONO, etc.). In certain examples, this silicon nitride layer can be formed by low-pressure chemical vapor deposition (LPCVD) to a thickness of about 3.5 nm to about 5 nm.

Referring to FIG. 4E, a collar oxide layer 800 is formed over the substrate 800 and on the sidewalls of the trench 416 above the capacitor node dielectric layer 700. The collar oxide layer 800 can be formed by depositing an oxide layer in the trench 416 using a chemical vapor deposition (CVD) process and portions of this layer is then etched to expose the upper storage node 705. The collar oxide layer 800 is formed approximately over the capacitor node dielectric layer 700. In this example, the collar oxide layer 800 is thicker than the capacitor node dielectric layer 700. Furthermore, in certain examples, the collar oxide layer 800 can have a thickness of about 40 nm to about 60 nm.

A storage node connecter 815 is formed by depositing a second polysilicon layer over the substrate 800 and on the collar oxide layer 800. The second polysilicon layer is recessed or etched back to a certain height above the storage node connector 815. For example, a chemical-mechanical polish (CMP) process can be used to remove portions of the polysilicon layer to a certain height above the storage node connector 815. After the polysilicon layer is etched back, exposed portions of the collar oxide layer 800 can be etched back to the same height as the storage node connector 815. In this example, the top surface of the collar oxide 800 is higher than that of the storage node connector 815. The resulting device is thus shown in FIG. 4E where the remaining polysilicon layer forms the storage node connector 815.

Referring to FIG. 4F, a selective Epi-Si growth process (e.g., a silicon vapor phase epitaxial growth process) is performed on portions of the substrate 400 at the sidewalls in the trench to form the Epi-Si layer 816 and on the storage node connector 815 which contains polysilicon. The silicon in the substrate 400 and polysilicon of the storage node connector 815 allows for the growth of the Epi-Si layer 815. The hard mask layer 410 and pad oxide layer 405 prevent Epi-Si growth in an upward direction towards the top surface of the substrate 400 and the collar oxide 800 prevents Epi-Si growth in the downward direction towards portions of the substrate 400 above the buried well region 435. In this example, the Epi-Si layer 816 formed from substrate 400 at the sidewalls of the trench will follow a crystal structure in the substrate 400 and the Epi-Si layer 817 formed on the polysilicon of the storage node connector 815 will follow a crystal structure in the polysilicon. The resulting device of FIG. 4F defines a bottle-shaped storage capacitor where the neck region is defined by the Epi-Si layer 816 and the lower portion of the bottle-shaped storage capacitor is defined by the upper storage node 705 and capacitor node dielectric 700.

Referring to FIG. 4G, a very thin buried strap nitride layer (not labeled) is formed on the storage node connector 815 and on the Epi-Si layer 816 using a nitridation process and then a capping layer 818 is formed by depositing polysilicon on the thin buried strap nitride layer. The polysilicon is etched or polished back to form the capping layer 816 as shown by the device in FIG. 4G. The buried strap nitride layer prevents impurities, such as As, from the polysilicon in the capping layer 416 from diffusing into the substrate 400. The resulting device allows a transistor to be connected to the bottle-shaped storage capacitor through the path of the capping layer 818 and storage node connector 815. In subsequent processes, the hard mask layer 410 and oxide pad layer 405 can be removed to form a transistor with and source and drain regions.

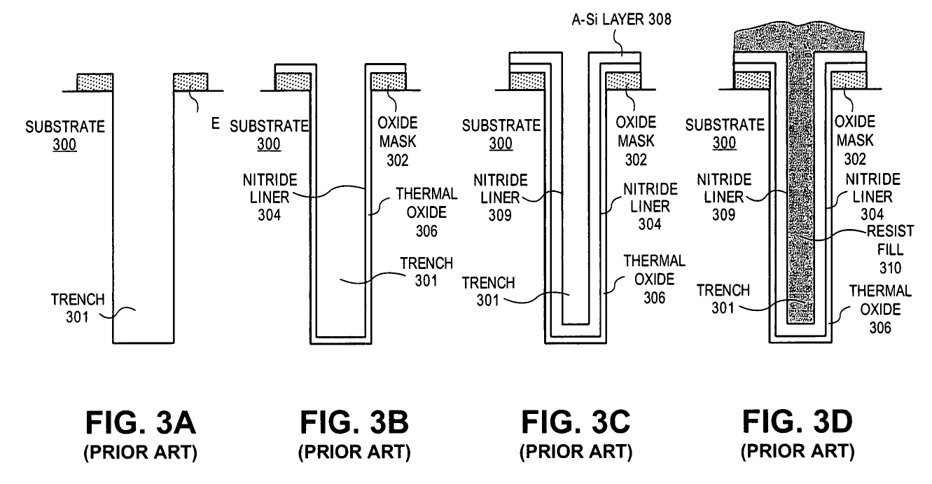

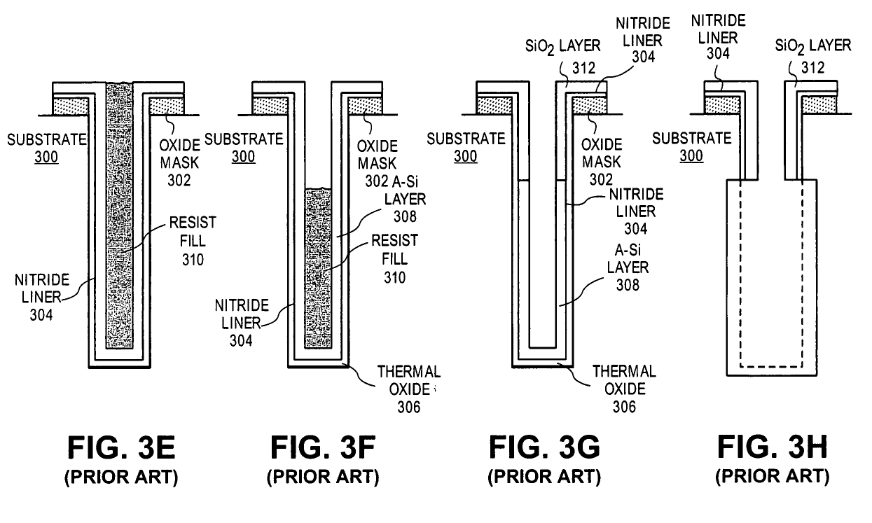

The above method allows a bottle-shaped storage capacitor to be formed wherein the bottom portion of the bottle-shaped storage capacitor is formed using the full opening of the trench. Thus, etching processes in the lower portion of the trench is more easily controlled in contrast to prior techniques. Furthermore, the length and width of the trench 416 during the etching process, e.g., shown in FIG. 4A, can be the similar dimensions that are used in conventional processes of forming a bottle-shaped deep trench during the wet etching process, e.g., shown in FIG. 3H.

FIGS. 5A-5C are cross-sectional diagrams of a semiconductor device to illustrate the steps of forming a bottle-shaped trench using a partial selective Epi-Si growth process for a storage capacitor according to one example. Referring to FIG. 5A, an oxide layer 591 is formed and patterned on a substrate 500 to form an oxide mask layer 591. The oxide mask layer 591 exposes portions of substrate 500, and then the exposed portions are etched to form a deep trench using, e.g., dry etching processes. A TEOS oxide layer 590 is then formed in the trench and over the substrate 500. The trench is then filled with a photoresist fill 592 and recessed or etched back to a first depth in the trench. The top portion of the TEOS oxide layer 590 is then etched back using a wet etch process, e.g., using a BHF solution, to the first depth. The photoresist fill 592 is then stripped or removed using, e.g., a wet etching process and the resulting device is shown in FIG. 5B.

Referring to FIG. 5C, using the resulting device of FIG. 5B, an Epi-Si growth process is performed on the portions of the substrate 500 on the sidewalls in the trench to form Epi-Si layer 595. An epitaxial layer is formed from the silicon in the substrate 500. The TEOS layer 590 in the lower portion of the trench is then removed or etched away using a wet etch process, e.g., using a BHF solution. The resulting device is shown in FIG. 5C. From this resulting device, a bottle-shaped trench is now formed having a neck portion defined by the Epi-Si layer 595 and body portion defined by the remaining trench that defines a bottle-shape.

Referring to FIG. 5D, a buried plate 596 is formed in the substrate 500. This process can be similar to the one described in the method of FIGS. 4A-4G. For example, an ASG layer, which can be covered by TEOS, is formed on the bottom of the trench and an annealing process can take place to diffuse dopants into the substrate 500 to form buried plate 596. The ASG layer can then be removed or stripped away using a wet etch process, e.g., using a BHF solution. Referring to FIG. 5E, a node dielectric layer 599 is formed in the trench. A first polysilicon layer 593 is then filled into the trench and on the node dielectric layer 599 and recessed and etched back to the predetermined depth under the Epi-Si layer 595. The node dielectric layer 599 is also removed to the predetermined depth corresponding to the first polysilicon layer 593. The first polysilicon layer 593 acts as an upper node for the storage capacitor.

Referring to FIG. 5F, a collar oxide layer 594 is formed on the sidewalls of the trench above the polysilicon layer 593. Subsequently, a second polysilicon layer 597 (acting as a storage node connector) is filled in the trench and portions of the collar oxide layer 594 is removed for exposing portions of the Epi-Si layer 595 and then a third polysilicon layer 598 (acting as a capping layer) is formed on the polysilicon layer 597 and collar oxide layer 594. The resulting device is shown in FIG. 5F where the oxide mask layer 591 can be removed for fabrication of a transistor with source and drain regions.

For the above methods in FIGS. 4A-4G and 5A-5F, a transistor can be subsequently formed on the substrate having source and drain regions formed in the Epi-Si growth regions or layers. Thus, the above techniques allow for larger deep trench masks to be patterned and utilized and allowing for a larger photolithography process window to reduce mask costs. The larger process window allows for deeper trenches to be formed. A bottle shaped deep trench profile can be obtained without transition from collar to node by wet process to prevent leakage concern.

In the foregoing specification, the invention has been described with reference to specific examples and embodiments. It will, however, be evident that various modifications and changes may be made thereto without departing from the broader spirit and scope of the invention as set forth in the appended claims. The specification and drawings are, accordingly, to be regarded in an illustrative rather than a restrictive sense.

What is claimed is:

1. A semiconductor fabrication method comprising:
forming a trench in a substrate; and
forming an Epi-Si layer from portions of the substrate such that the Epi-Si layer is used to define a bottle-shape for the trench.

2. The method of claim 1, wherein forming the trench includes forming a deep trench.

3. The method of claim 2, further comprising:
forming a buried plate in the substrate by diffusing dopants from a dopant layer formed in the deep trench.

4. The method of claim 3, further comprising:
forming a capacitor node dielectric layer in the deep trench;
forming a first polysilicon layer in the deep trench;
forming a collar oxide layer over the first polysilicon layer and capacitor node dielectric layer;
forming a second polysilicon layer on the first polysilicon layer; and
forming a third polysilicon layer over the second polysilicon layer.

5. The method of claim 4, wherein the first, second, and third polysilicon layers act as storage node, node connector, and capping node layers, respectively.

6. The method of claim 5, further comprising:
forming an electrical connection between a transistor and the capping node layers.

7. A semiconductor device comprising:
a substrate with a trench formed therein; and
an Epi-Si layer formed from portions of the substrate such that the Epi-Si layer is used to define a bottle-shape for the trench.

8. The semiconductor device of claim 7, wherein the trench includes a deep trench.

9. The semiconductor device of claim 8, further comprising:
a buried plate formed in the substrate from dopants diffused from a dopant layer formed in the deep trench.

10. The semiconductor device of claim 9, further comprising:
a capacitor node dielectric layer formed in the deep trench;
a first polysilicon layer formed in the deep trench;
a collar oxide layer formed over the first polysilicon layer and capacitor node dielectric layer;
a second polysilicon layer formed on the first polysilicon layer; and
a third polysilicon layer formed over the second polysilicon layer.

11. The semiconductor device of claim 10, wherein the first, second, and third polysilicon layers include storage node, node connector, and capping node layers, respectively.

12. The semiconductor device of claim 11, further comprising:
forming an electrical connection between a transistor and at least the capping node layer.

13. A semiconductor device comprising:
a transistor having source and drain regions formed on a substrate; and
a storage capacitor coupled to the transistor, the storage capacitor formed from a bottle-shaped trench and having and an Epi-Si layer grown inside the trench to form at least part of one of the source and drain regions.

14. The semiconductor device of claim 13, wherein the Epi-Si layer is selectively grown on sidewalls of a top section of the trench.

15. The semiconductor device of claim 14, wherein the Epi-Si layer is used to define the bottle-shape for the trench.

16. The semiconductor device of claim 13, wherein the storage capacitor further comprises:
a conductive connecting layer capable of connecting with a source region of the transistor.

17. The semiconductor device of claim 16, further comprising:
one or more polysilicon layers to that form part of the conductive connecting layer.

18. A semiconductor fabrication method comprising:
forming a transistor having source and drain regions formed on a substrate; and
forming a storage capacitor coupled to the transistor, the storage capacitor formed from a bottle-shaped trench and having an Epi-Si layer grown inside the trench to form at least part of one of the source and drain regions.

19. The method of claim 18, wherein forming the storage capacitor includes growing an epitaxial layer from portions of silicon in the substrate.

20. The method of claim 19, wherein the epitaxial layer is formed from portions of the substrate that define a sidewall in a top section of the trench.
